(19) United States
(12) Patent Application Publication
(10) Pub. No.: US 2024/0234614 A1
(43) Pub. Date: Jul. 11, 2024

(54) ULTRAVIOLET SENSOR

(71) Applicants: Jae Hyuk PARK, Gyeonggi-do (KR); HYPER MATERIALS, INC., Gyeonggi-do (KR)

(72) Inventor: Jae Hyuk PARK, Gyeonggi-do (KR)

(21) Appl. No.: 18/561,205

(22) PCT Filed: May 3, 2023
(86) PCT No.: PCT/KR2023/006016

§ 371 Date: Nov. 15, 2023

(30) Foreign Application Priority Data
May 3, 2022 (KR) 10-2022-0054744
May 2, 2023 (KR) 10-2023-0056953

(51) Int. Cl. H01L 31/09; H01L 31/0203; H01L 31/0224; H01L 31/0368

(52) U.S. Cl. CPC H01L 31/09; H01L 31/0203; H01L 31/0224; H01L 31/0368

(57) ABSTRACT

The present disclosure relates to an ultraviolet sensor, and an object of the present disclosure is to provide a simple, low-cost, and highly efficient ultraviolet sensor by aerosol deposition. For this, an ultraviolet sensor includes a substrate, a polycrystalline film formed by spraying powder having an energy bandgap of 3 eV to 11 eV and an average central particle size of 0.1 μm to 5 μm onto the substrate in a vacuum at a speed of 100 m/s to 500 m/s through a nozzle, wherein the polycrystalline film has an average central particle size of 1 nm to 500 nm, and at least two electrodes provided on the polycrystalline film.

### TECHNICAL FIELD

The present disclosure relates to an ultraviolet sensor.

### BACKGROUND ART

Ultraviolet rays (hereinafter, referred to as an UV) are invisible light having a very short wavelength of less than about 400 nm. Most of the UV are absorbed by an ozone layer and thus do not reach the earth's surface, but when the UV touches the skin, the UV is strong enough to destroy cells and genes and thus useful for sterilization and the like. On the other hand, when used in real life, the UV is light in a wavelength band, which requires detailed management to protect the human body. There are attempts that the UV is not only applied to sterilization for water quality management, but also uses a short wavelength band to attempt to be utilized in military fields such as military communications, radar, and biological weapon detection, in environmental fields such as ozone and fine dust sensing, and in industrial fields for flame detection such as fire or arc discharge, etc.

An ultraviolet (UV) sensor that is currently used may use an AlN (e.g., ˜ 6.28 eV) material that is capable of sensing a wavelength of approximately 200 nm or less, or a GaN (e.g., ˜3.44 eV) material that is capable of sensing a wavelength band of approximately 350 nm, and sensing of a mid-wavelength band is implemented by controlling a composition ratio of AlN and GaN. AlN- and GaN-based materials have to be grown into an epitaxy layer using high temperature and expensive equipment such as chemical vapor deposition (CVD) and molecular beam epitaxy (MBE) due to their characteristics. However, AlN and GaN are difficult to be deposited as an epitaxial layer due to lattice mismatch, and thus, a method of stacking a plurality of layers (for example, buffer layer) is being mainly used.

However, when implementing a sensor using this method, it has the disadvantage of not being to be used in a variety of ways because a manufacturing time is very long, costs are high, and a thickness of the device is thick. In addition, an AlGaN optical sensor, which is used by mixing AlN and GaN, has problems of longer response and recovery time compared to when a single material is used, and thus, there is a limitation in sensing time.

Research is being also conducted to develop an ultraviolet sensor using a ZnO-based material as another optical sensor, but due to limitations in bandgap, there is a problem of low reactivity as external quantum efficiency (EQE) is significantly lowered at a wavelength of 400 nm or less.

The above-described information disclosed in the technology that serves as the background of the present disclosure is only for improving understanding of the background of the present disclosure and thus may include information that does not constitute the related art.

### DISCLOSURE OF THE INVENTION

### Technical Problem

An object of the present disclosure is to provide a method for simply manufacturing a high-efficiency ultraviolet sensor at a low cost by aerosol deposition, and an ultraviolet sensor manufactured therethrough.

### Technical Solution

An exemplary ultraviolet sensor according to the present disclosure may include: a substrate; a polycrystalline film formed by spraying powder having an energy bandgap of 3 eV to 11 eV and an average central particle size of 0.1 μm to 5 μm onto the substrate in a vacuum at a speed of 100 m/s to 500 m/s through a nozzle, wherein the polycrystalline film has an average central particle size of 1 nm to 500 nm; and at least two electrodes provided on the polycrystalline film.

In some embodiments, the substrate may include silicon, quartz, sapphire, a polymer, or a metal.

In some embodiments, the powder may include at least one of MgF₂, BeO, GaF₂, SiO₂, ZrO₂, MgO, Al₂O₃, AlN, HfO₂, GeO₂, LaAlO₃, diamond, α-Si₃N₄, β-Ga₂O₃, Yb₂O₃, Nd₂O₃, Zn₂GeO₄, Ta₂O₅, MgS, In₂Ge₂O₇, ZnS, NiO, In₂O₃, Zn₂SnO₄, SnO₂, Nb₂O₅, GaN, ZnO, WO₃, CeO₂, 4H-SiC, TiO₂, NgNiO, MgZnO, BeMgZnO, MgZnS, AlGaN, ZrTiO₂, or InGaZnO.

In some embodiments, the polycrystalline film may have a thickness of 1 nm to 50 μm.

In some embodiments, the at least two electrodes may be provided in an interdigital form on the polycrystalline film.

In some embodiments, the at least two electrodes may include a first electrode provided on the substrate and a second electrode provided on the polycrystalline film crossing the first electrode.

In some embodiments, each of the electrode may have specific resistance less than 100 ohm/cm.

In some embodiments, the polycrystalline film and the electrode may be covered by a protective layer, and the protective layer has light transmittance of 50% to 99.9%.

In some embodiments, the ultraviolet sensor may be configured to sense light having a wavelength of 10 nm to 400 nm.

In some embodiments, the substrate and the polycrystalline film may have a concave structure to improve sensing sensitivity or a convex structure to increase in sealing area.

### Advantageous Effects

The present disclosure may provide the method for simply manufacturing the high-efficiency ultraviolet sensor at the low cost by the aerosol deposition, and the ultraviolet sensor manufactured therethrough.

### BRIEF DESCRIPTION OF THE DRAWINGS

FIG. 1 is a schematic view illustrating an apparatus for manufacturing an ultraviolet sensor by exemplary aerosol deposition according to the present disclosure.

FIG. 2 is a flowchart illustrating a method for manufacturing an ultraviolet sensor by exemplary aerosol deposition according to the present disclosure.

FIGS. 3a and 3b are plan and cross-sectional views illustrating an ultraviolet sensor by exemplary aerosol deposition according to the present disclosure.

FIG. 4 is a view illustrating characteristics of the ultraviolet sensor by the exemplary aerosol deposition according to the present disclosure (heat treatment at a temperature of 800° C.).

FIG. 5 is a view illustrating characteristics of the ultraviolet sensor by the exemplary aerosol deposition according to the present disclosure (heat treatment at a temperature of 600° C.).

FIG. 6 is a view illustrating characteristics of the ultraviolet sensor by the exemplary aerosol deposition according to the present disclosure (no heat treatment).

FIGS. 7a and 7b are graphs illustrating output current and an on/off ratio depending on an electrode length in the ultraviolet sensor by the exemplary aerosol deposition according to the present disclosure.

FIG. 8 is a graph illustrating output current at an mA level depending on an electrode length in the ultraviolet sensor by the exemplary aerosol deposition according to the present disclosure.

FIG. 9 is a graph illustrating results obtained by comparing transparency of a polycrystalline film depending on a powder size in the ultraviolet sensor by the exemplary aerosol deposition according to the present disclosure.

FIG. 10 is a cross-sectional view illustrating an ultraviolet sensor by the exemplary aerosol deposition according to the present disclosure.

FIG. 11 is a cross-sectional view illustrating an ultraviolet sensor by the exemplary aerosol deposition according to the present disclosure.

FIGS. 12a and 12b are cross-sectional views illustrating an ultraviolet sensor by the exemplary aerosol deposition according to the present disclosure.

### MODE FOR CARRYING OUT THE INVENTION

Hereinafter, embodiments will be described in detail with reference to the accompanying drawings.

The present disclosures may, however, be embodied in many different forms and should not be construed as being limited to the embodiments set forth herein; rather, these embodiments are provided so that those skilled in the art thoroughly understand the present disclosure. Rather, these embodiments are provided so that this disclosure will be thorough and complete, and will fully convey the scope of the present disclosure to those skilled in the art.

In addition, in the following drawings, the thickness or size of each layer is exaggerated for convenience and clarity of description, and the same reference numerals in the drawings refer to the same elements. As used herein, the term “and/or” includes any and all combinations of one or more of the associated listed items. In this specification, it will also be understood that if a member A is referred to as being connected to a member B, the member A can be directly connected to the member B or indirectly connected to the member B with a member B therebetween.

The terms used in this specification are for illustrative purposes of the present disclosure only and should not be construed to limit the meaning or the scope of the present disclosure. As used in this specification, a singular form may, unless definitely indicating a particular case in terms of the context, include a plural form. Also, the expressions “comprise/include” and/or “comprising/including” used in this specification neither define the mentioned shapes, numbers, steps, operations, members, elements, and/or groups of these, nor exclude the presence or addition of one or more other different shapes, numbers, steps, operations, members, elements, and/or groups of these, or addition of these. The term “and/or” used herein includes any and all combinations of one or more of the associated listed items.

As used herein, terms such as “first,” “second,” etc. are used to describe various members, components, areas, layers, and/or portions. However, it is obvious that the members, components, areas, layers, and/or portions should not be defined by these terms. The terms do not mean a particular order, up and down, or superiority, and are used only for distinguishing one member, component, region, layer, or portion from another member, component, region, layer, or portion. Thus, a first member, component, region, layer, or portion which will be described may also refer to a second member, component, region, layer, or portion, without departing from the teaching of the present disclosure.

Spatially relative terms, such as “below”, “beneath”, “lower”, “above”, “upper” and the like, may be used herein for ease of description to describe one element or feature's relationship to another element(s) or feature(s) as illustrated in the figures. These spatially relative terms are intended for easy comprehension of the prevent invention according to various process states or usage states of the prevent invention, and thus, the present disclosure is not limited thereto. For example, an element or feature shown in the drawings is turned inside out, the element or feature described as “beneath” or “below” may change into “above” or “upper”. Thus, the term “lower” may encompass the term “upper” or “below”.

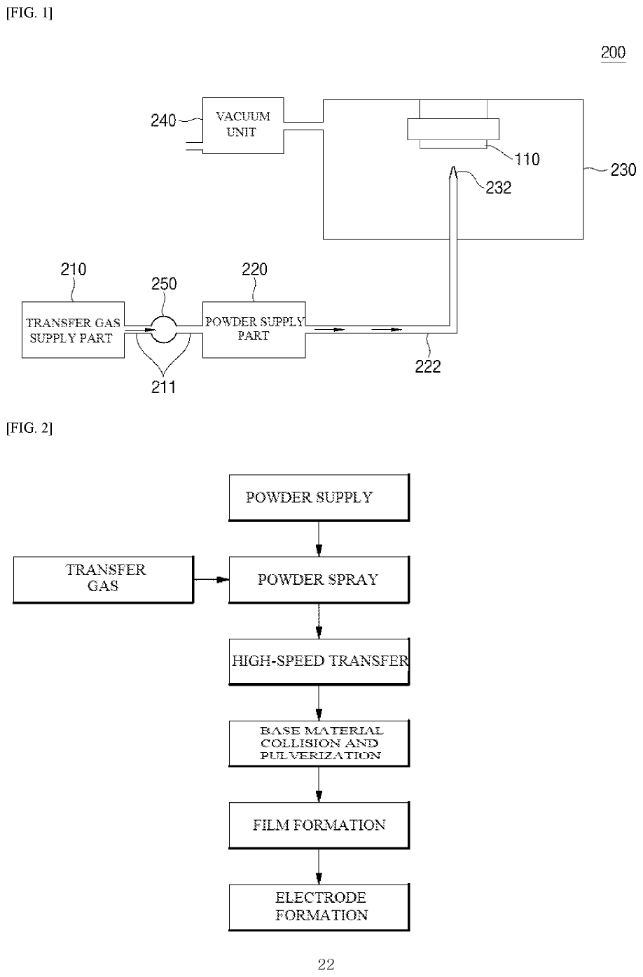

FIG. 1 is a schematic view illustrating an apparatus for manufacturing an ultraviolet sensor by exemplary aerosol deposition according to the present disclosure, and FIG. 2 is a flowchart illustrating a method for manufacturing an ultraviolet sensor by exemplary aerosol deposition according to the present disclosure.

As illustrated in FIG. 1, an apparatus 200 for manufacturing an ultraviolet sensor according to the present invention may include a transfer gas supply part 210, a powder supply part 220 that stores and supplies one type of powder or a mixture of several types of powder, which has an energy bandgap of approximately 3 eV to approximately 11 eV, a transfer tube 222 that transfers powder from the powder supply part 220 at a high speed using a transfer gas, a nozzle 232 that applies/stacks or sprays the powder from the transfer tube 222 to an insulating or conductive substrate 110, and a vacuum chamber 230 in which the powder sprayed from the nozzle 232 collides to crush a surface of the substrate 110 so as to form a polycrystalline film having a predetermined thickness.

Referring to FIGS. 1 and 2 together, a method for forming the polycrystalline film according to the present invention will be described.

The transfer gas stored in the transfer gas supply part 210 may include oxygen, helium, nitrogen, argon, carbon dioxide, hydrogen, or air. The transfer gas may be directly supplied from the transfer gas supply part 210 to the powder supply part 220 through a pipe 211 to adjust a flow rate and a pressure by a flow rate controller 250.

The powder supply part 220 may store and supply a large amount of powder, and the powder may have an average central particle size range of approximately 0.1 μm to approximately 5 μm. In some embodiments, the powder may have a spherical, polygonal, or needle shape.

If the average central particle size range of the powder is less than approximately 0.1 μm, not only it is difficult to store and supply the powder, but also it is easy to form a powder compact, in which particles having particle size of approximately 0.1 μm are aggregated, during spraying, collision, crushing and/or pulverization due to agglomeration phenomenon during the powder storage and supply and also difficult to form a large-area polycrystalline film. Substantially, if the average central particle size range of the powder is less than approximately 0.1 μm, the formation of the polycrystalline film does not occur. In addition, if the average center particle size range of the powder is larger than approximately 5 mm, not only it is easy to cause a sandblasting phenomenon, which involves peeling of the substrate during the spraying, the collision, crushing, and/or the pulverization of the powder, but also the particle size within the partially formed polycrystalline film is relatively large to allow a structure of the polycrystalline film to be unstable and allow porosity inside or in a surface of the polycrystalline film to increase, thereby preventing the material from exhibiting its original properties.

If the average central particle size of the powder ranges from approximately 0.1 μm to approximately 5 μm, the polycrystalline film having relatively small porosity (porous ratio), no surface micro-crack phenomenon, and easy powder control may be obtained. In addition, if the average central particle size of the powder ranges from approximately 0.1 μm to approximately 5 μm, the polycrystalline film can be obtained at a relatively high lamination speed, is transparent (or translucent), and has easy material properties. In some embodiments, if the average central particle size of the powder ranges from approximately 0.1 μm to approximately 5 μm, the polycrystalline film in which the average central particle size ranges from approximately 1 nm to approximately 500 nm may be obtained.

The vacuum chamber 230 may maintain a vacuum state during the formation of the polycrystalline film, and a vacuum unit 240 may be connected to this purpose. More specifically, a pressure of the vacuum chamber 230 is approximately 1 torr (low vacuum) to approximately 760 torr (atmospheric pressure), and a pressure of the powder transferred by the high-speed transfer tube 222 may be greater than that of the vacuum chamber 230.

Furthermore, an internal temperature range of the vacuum chamber 230 is approximately 0° C. to approximately 30° C., and thus, there may be no separate member for increasing or decreasing in internal temperature of the vacuum chamber 230. That is, the transfer gas and/or the substrate may not be separately heated and may be maintained at a temperature of approximately 0° C. to approximately 30° C.

In some embodiments, to improve deposition efficiency and density of the polycrystalline film, the transfer gas or/and the substrate may be heated to a temperature of approximately 30° C. to approximately 1000° C. That is, the transfer gas in the transfer gas supply part 210 may be heated by a separate heater (not shown), or the substrate 111 in the vacuum chamber 230 may be heated by a separate heater (not shown). Stress applied to the powder when forming the polycrystalline film by heating the transfer gas and/or the substrate may be reduced to obtain the dense polycrystalline film having the small porosity. Here, if the temperature of the transfer gas or/and the substrate is higher than approximately 1000° ° C., the powder may be melted to causes a rapid phase transition, and thus, the porosity of the polycrystalline film may increase, and the internal structure of the polycrystalline film may be unstable. In addition, if the transfer gas or/and the substrate temperature is less than approximately 30° C., the stress applied to the powder may not be reduced.

However, the temperature range may not be limited in the present invention, and the internal temperature range of the transfer gas, the substrate, and/or the vacuum chamber may be adjusted between approximately 0° C. and approximately 1000° C. depending on characteristics of the substrate on which the polycrystalline film is to be formed.

As described above, a pressure difference between the vacuum chamber 230 and the high-speed transfer tube 222 (or the transfer gas supply part 210 or the powder supply part 220) may be approximately 1.5 times to approximately 2000 times. If the pressure difference is less than approximately 1.5 times, the high-speed transfer of the powder may be difficult, and if the pressure difference is greater than approximately 2000 times, the surface of the substrate may be excessively etched by the powder.

According to the pressure difference between the vacuum chamber 230 and the transfer tube 222, the powder from the powder supply part 220 may be sprayed through the transfer tube 222 and be transferred to the vacuum chamber 230 at a high speed.

In addition, the nozzle 232 connected to the transfer tube 222 may be provided in the vacuum chamber 230 to allow the powder to collide with the substrate 110 at a speed of approximately 100 m/s to approximately 500 m/s. That is, the powder passing through the nozzle 232 may be crushed and/or pulverized by the kinetic energy obtained during the transferring and the collision energy generated during the high-speed collision to form the polycrystalline film having a predetermined thickness on the surface of the substrate 110. In some embodiments, the method of forming the polycrystalline film may also be referred to as aerosol deposition.

As described above, when the average central particle size of the powder is approximately 1 μm to approximately 5 μm, the polycrystalline film having the average central particle size of approximately 1 nm to approximately 500 nm may be obtained. For example, the thickness of the polycrystalline film is approximately 1 nm to approximately 50 μm.

When the thickness of the polycrystalline film exceeds approximately 50 μm, there is a problem in that a flexible device may not be implemented due to a thick channel region exceeding approximately 50 μm even when applied to the flexible substrate. In addition, it may be very difficult to control the thickness of the polycrystalline film to less than approximately 1 nm, and a thin film that is too thin may have rather weak photoreactivity. As a result, the thickness of the polycrystalline film may be preferably approximately 1 nm to approximately 50 μm, and more preferably approximately 10 nm to approximately 10 μm.

A process of forming an electrode may be performed after the process of forming the polycrystalline film. In some embodiments, the electrode formation process may be performed through electron beam, sputtering, or chemical vapor deposition. In some embodiments, the process of forming the electrode may include a process of depositing a titanium layer on the polycrystalline film through the electron beam and a process of depositing a gold layer or platinum layer on the titanium layer through the electron beam. In some embodiments, the titanium layer may serve to allow the gold layer to adhere to the polycrystalline film, and the gold layer may serve as a wire through which electrons easily flow. In some embodiments, the electrode may be applicable to the present invention if the electrode is made of a conductive material having resistivity less than approximately 200 ohm/cm, preferably less than approximately 100 ohm/cm.

In some embodiments, the thickness of the electrode may be approximately 10 nm to approximately 200 nm. In some embodiments, the thickness of the titanium layer may be approximately 20 nm to approximately 40 nm, and the thickness of the gold layer may be approximately 100 nm to approximately 200 nm.

A heat treatment process may be further performed after the above-described polycrystalline film formation process and/or electrode formation process. In some embodiments, the polycrystalline film may be heat treated at a temperature of approximately 100° C. to approximately 1500° C. for approximately 1 minute to approximately 600 minutes. A response and recovery speed of the ultraviolet sensor may be improved by the heat treatment. In some embodiments, the heat treatment may be performed by putting the substrate, on which the above-described polycrystalline film is formed, into a furnace, or by directly radiating laser beam or ion beam to the polycrystalline film.

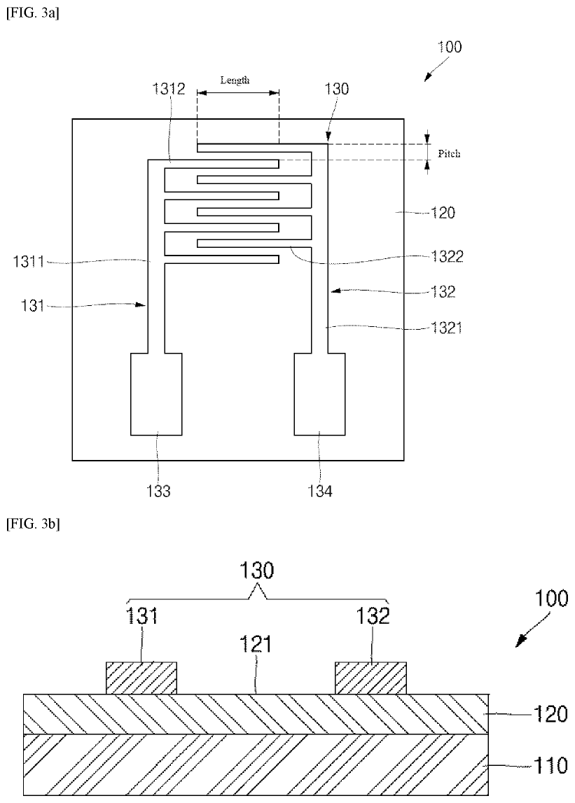

FIGS. 3a and 3b are plan and cross-sectional views illustrating an ultraviolet sensor 100 by exemplary aerosol deposition according to the present disclosure.

As illustrated in FIGS. 3a and 3b, the ultraviolet sensor 100 may include a substrate 110, a polycrystalline film 120, and a pair of electrodes 130.

The substrate 110 may be used in a variety of ways, from rigid and inflexible substrates to flexible substrates without any particular limitation. In addition, a variety of substrates 110 may be used without any particular limitation in the field of insulating substrates to conductive substrates. In some embodiments, the substrate 110 may include a silicon substrate, a quartz substrate, a sapphire substrate, a polymer substrate, a high molecule substrate, or a metal substrate.

The polycrystalline film 120 may be formed on the substrate 110 by aerosol deposition as described above. The polycrystalline film 120 may be formed in the form of a two-dimensional thin film. In this case, the polycrystalline film 120 may be a crystalline having a poly alpha α,β phase or a crystalline having a poly β phase. The polycrystalline film 120 may be formed through the aerosol deposition method as described above. In this way, the deposition process may be performed at least once to easily provide the polycrystalline film, the crystal film having a poly α,β phase, or the crystal film having poly β phase.

As described above, the polycrystalline film 120 may be formed on the substrate 110 by spraying one type of powder or a mixture of several types of powder with an energy bandgap of approximately 3 eV to approximately 11 eV in a vacuum at a speed of approximately 100 m/s to approximately 500 m/s through the nozzle. Here, the average central particle size of the powder forming the polycrystalline film 120 may be approximately 1 nm to approximately 500 nm.

In some embodiments, the powder may include at least one of MgF₂, BeO, GaF₂, SiO₂, ZrO₂, MgO, Al₂O₃, AlN, HfO₂, GeO₂, LaAlO₃, diamond, α-Si₃N₄, β-Ga₂O₃, Yb₂O₃, Nd₂O₃, Zn₂GeO₄, Ta₂O₅, MgS, In₂Ge₂O₇, ZnS, NiO, In₂O₃, Zn₂SnO₄, SnO₂, Nb₂O₅, GaN, ZnO, WO₃, CeO₂, 4H-SiC, TiO₂, NgNiO, MgZnO, BeMgZnO, MgZnS, AlGaN, ZrTiO₂, or InGaZnO.

In some embodiments, the powder such as MgF₂, BeO, GaF₂, SiO₂, ZrO₂, MgO, Al₂O₃, AlN, HfO₂, GeO₂, LaAlO₃, diamond, α-Si₃N₄, β-Ga₂O₃, Yb₂O₃, Nd₂O₃, Zn₂GeO₄, Ta₂O₅, MgS, or In₂Ge₂O₇ may have an energy bandgap of approximately 4 eV to 11 eV, and thus, an ultraviolet sensor capable of detecting an UVC region of approximately 10 nm to approximately 280 nm may be provided.

In some embodiments, the powder such as ZnS, NiO, In₂O₃, Zn₂SnO₄, SnO₂, Nb₂O₅, GaN, ZnO, WO₃, CeO₂, 4H-SiC, or TiO₂ may have an energy bandgap of approximately 3 eV to 4 eV, and thus, an ultraviolet sensor capable of detecting an UVA range of approximately 280 nm to approximately 400 nm may be provided.

In some embodiments, semiconductor alloy powder such as NgNiO, MgZnO, BeMgZnO, MgZnS, AlGaN, ZrTiO₂ or InGaZnO may have an energy bandgap of approximately 3 eV to approximately 11 eV, and thus, an ultraviolet sensor capable of detecting all of the UVC region, UVB region, and the UVC region of approximately 10 nm to 400 nm may be provided.

The pair of electrodes 130 may be disposed to be spaced apart from each other while being in direct contact with the surface of the transparent polycrystalline film 120, and thus, a channel region 121 may be provided within the polycrystalline film 120. Due to this structure, a metal-semiconductor-metal (MSM) structure may be provided. As described above, the two electrodes 130 may be made of titanium/gold or titanium/platinum, and may also be made of chrome/gold.

The two electrodes 130 may face each other and be spaced apart from each other, and thus, the channel region 121 in the polycrystalline film 120 may be exposed between the electrodes 130, and the exposed portion may be a sensing region of the optical sensor 100. That is, the channel region or channel 121 may be a sensing region.

In some embodiments, the two electrodes 130 may be provided as an interdigital transducer (IDT) type. In some embodiments, the electrode 131 at one side may be constituted by one main electrode 1311 and a plurality of sub-electrodes 1312 extending from the main electrode 1311, and the electrode 132 at the other side may also be constituted by one main electrode 1311 and a plurality of sub-electrodes 1322 extending from the main electrode 1321.

In some embodiments, the main electrode 1311 at one side and the main electrode 1321 at the other side may face each other and be spaced apart from each other, and the sub-electrodes 1312 at one side and the sub-electrodes 1322 at the other side may also be alternately disposed and spaced apart from each other. In the drawing, unexplained numerals 133 and 134 may denote electrode pads that are electrically connected to the power supply and the current sensor, respectively.

In some embodiments, the channel region 121 of the polycrystalline film 120 may be exposed to the outside by the sub-electrode 1312 at one side and the sub-electrode 1322 at the other side. The channel region 121 may have a predetermined length and a predetermined pitch. In some embodiments, the number of pair of sub-electrodes 1312 and 1322 may be approximately 10 to approximately 100,000, and the total length of the channel region 121 may be determined depending on the number or pitch of the sub-electrodes 1312 and 1322. In some embodiments, the total length of the channel region 121 may be approximately 20 mm to approximately 30,000 mm.

The ultraviolet sensor 100 having the manufacturing method and structure as described above may not only have excellent wavelength selectivity by absorbing only ultraviolet rays without absorbing visible light, but also have a cheaper manufacturing cost and a relatively fast response speed compared to the related art.

For example, the ultraviolet sensor 100 according to the present disclosure may sense light having a wavelength of approximately 10 nm to approximately 400 nm. In addition, the ultraviolet sensor 100 according to the present disclosure may have a response speed of approximately 0.1 s to approximately 4 s. In addition, the ultraviolet sensor 100 according to the present disclosure may have an output current ratio (reaction, response, or sensitivity) of approximately 6 times to approximately 40,000 times when exposed to the ultraviolet rays and when not exposed to the ultraviolet rays.

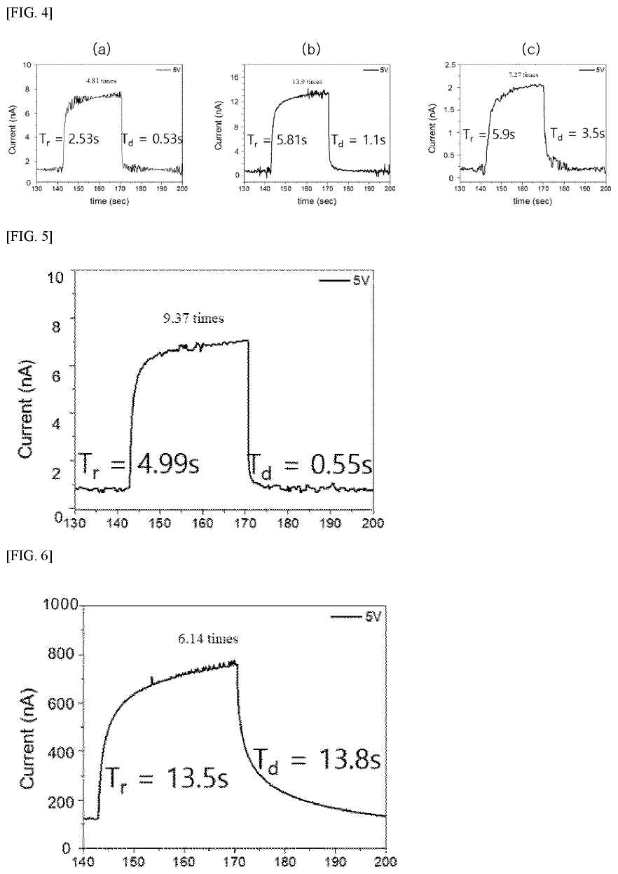

FIG. 4 is a view illustrating characteristics of a Ga₂O₃ ultraviolet sensor by the exemplary aerosol deposition according to the present disclosure (heat treatment at a temperature of 800° C.). Here, (a) illustrates a characteristic diagram after heat treatment at a temperature of 800° ° C. for 5 minutes, (b) illustrates a characteristic diagram after heat treatment at a temperature of 800° C. for 15 minutes, and (c) illustrates a characteristic diagram after heat treatment at a temperature of 800° ° C. for 30 minutes.

The Ga₂O₃ ultraviolet sensor as illustrated in (a) of FIG. 4 may see a response time of approximately 2.53 seconds (time for an output current value to reach a maximum value) when UV rays are illuminated, and see a recovery time of approximately 0.53 seconds (time when an output current value to reach a lowest value) when the UV rays are blocked, and also, it is seen that an output current ratio with and without ultraviolet rays is approximately 4.81 times.

The Ga₂O₃ ultraviolet sensor as illustrated in (b) of FIG. 4 may see a response time of approximately 5.81 seconds (time for an output current value to reach a maximum value) when UV rays are turned on, and see a recovery time of approximately 3 seconds (time when an output current value to reach a lowest value) when the UV rays are turned off, and also, it is seen that an output current ratio with and without ultraviolet rays is approximately 13.9 times.

The Ga₂O₃ ultraviolet sensor as illustrated in (a) of FIG. 4 may see a response time of approximately 5.9 seconds (time for an output current value to reach a maximum value) when UV rays are turned on, and see a recovery time of approximately 3.5 seconds (time when an output current value to reach a lowest value) when the UV rays are turned off, and also, it is seen that an output current ratio with and without ultraviolet rays is approximately 7.27 times.

FIG. 5 is a view illustrating characteristics of the Ga₂O₃ ultraviolet sensor by the exemplary aerosol deposition according to the present disclosure (heat treatment at a temperature of 600° C.). The Ga₂O₃ ultraviolet sensor as illustrated in FIG. 5 may see a response time of approximately 4.99 seconds (time for an output current value to reach a maximum value) when UV rays are turned on, and see a recovery time of approximately 0.55 seconds (time when an output current value to reach a lowest value) when the UV rays are turned off, and also, it is seen that an output current ratio with and without ultraviolet rays is approximately 9.37 times.

FIG. 6 is a view illustrating characteristics of the Ga₂O₃ ultraviolet sensor by the exemplary aerosol deposition according to the present disclosure (no heat treatment). The Ga₂O₃ ultraviolet sensor as illustrated in FIG. 6 may see a response time of approximately 13.5 seconds (time for an output current value to reach a maximum value) when UV rays are turned on, and see a recovery time of approximately 13.8 seconds (time when an output current value to reach a lowest value) when the UV rays are turned off, and also, it is seen that an output current ratio with and without ultraviolet rays is approximately 6.14 times.

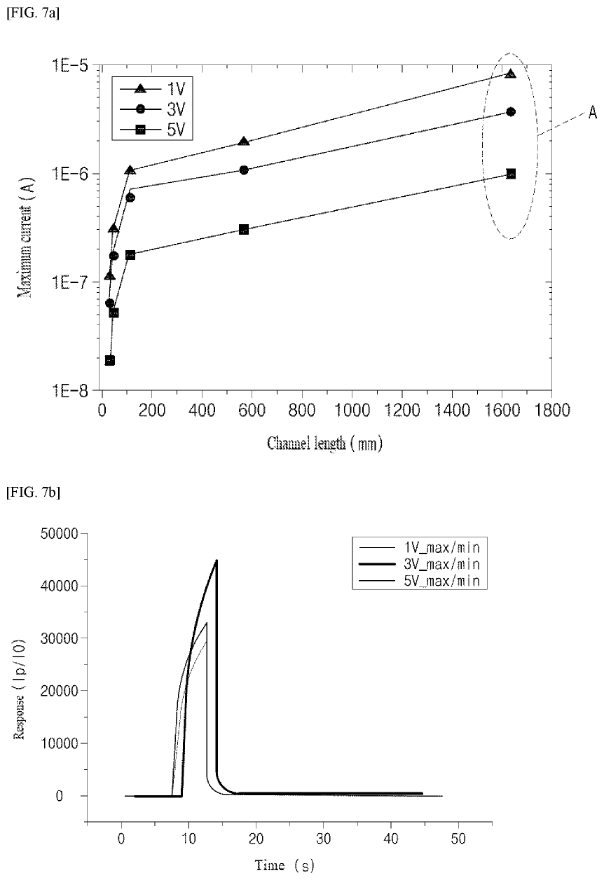

FIGS. 7a and 7b are graphs illustrating output current and an on/off ratio depending on an electrode length in the ultraviolet sensor by the exemplary aerosol deposition according to the present disclosure. The on/off ratio for the portion marked “A” in FIG. 7a is illustrated in FIG. 7b. Here, the ultraviolet sensor may be made of Ga₂O₃.

In the left drawing of FIG. 7a, an X-axis is a length of the channel region (mm), and a Y-axis is maximum current (A). In FIG. 7b, the X-axis is time, and the Y-axis is reaction, response or sensitivity (Ip/IO). In some embodiments, the length of the channel region may be approximately 10 mm to approximately 1800 mm.

As illustrated in FIG. 7a, when ultraviolet rays were irradiated in a state in which bias direct current voltages of 1V, 3V, and 5V are respectively applied to the pair of electrodes provided in the Ga₂O₃ ultraviolet sensor according to the present disclosure, the maximum current A was output. As each of the applied bias DC voltages increases, the maximum current flowing in response to the ultraviolet rays increased. In particular, as the length of the channel region became longer, the maximum current increased.

As illustrated in FIG. 7b, response characteristics or sensitivity were better when the bias DC voltage of 3V is applied than when the bias DC voltages of 1V and 5V are applied. In some embodiments, a sensitivity ratio of the ultraviolet sensor according to the present invention before and after the ultraviolet irradiation is irradiated was observed to approximately 40,000 times.

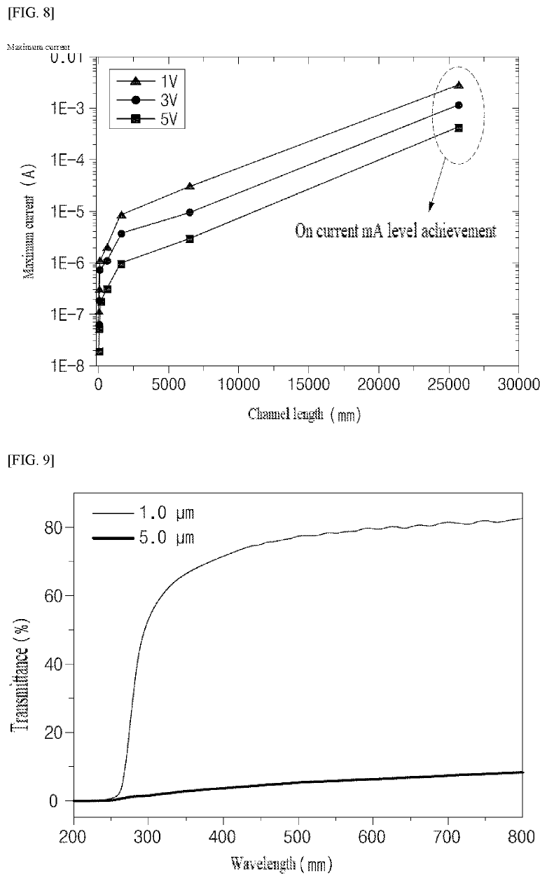

FIG. 8 is a graph illustrating output current at an mA level depending on an electrode length in the ultraviolet sensor by the exemplary aerosol deposition according to the present disclosure. Here, the ultraviolet sensor may be made of Ga₂O₃. In FIG. 8, an X-axis is a length of the channel region (mm), and a Y-axis is maximum current (A). In some embodiments, the length of the channel region may be approximately 10 mm to approximately 30,000 mm.

As illustrated in FIG. 8, when ultraviolet rays were irradiated in a state in which bias direct current voltages of 1V, 3V, and 5V are respectively applied to the pair of electrodes provided in the Ga₂O₃ ultraviolet sensor according to the present disclosure, the maximum current A was output. As each of the applied bias DC voltages increases, the maximum current flowing in response to the ultraviolet rays increased, and also, as the length of the channel region became longer, the maximum current increased. In some embodiments, when the length of the channel region exceeds approximately 25,000 mm, the maximum current of several mA flows, and thus, a sensing signal may be processed by a simple signal processing circuit having the relatively small number of amplifier circuits. Therefore, a price of the ultraviolet sensor may be lowered.

FIG. 9 is a graph illustrating results obtained by comparing transparency of a polycrystalline film depending on a powder size in the ultraviolet sensor by the exemplary aerosol deposition according to the present disclosure. In FIG. 9, an X-axis represents a wavelength (nm), and a Y-axis represents light transmittance (%).

As illustrated in FIG. 9, when a polycrystalline film is provided as powder having an average central particle size of approximately 1 μm, light transmittance of approximately 60% to approximately 80% was observed for light having a wavelength of approximately 300 nm to approximately 800 nm. However, when a polycrystalline film is provided as powder having an average central particle size of approximately 5 rem, light transmittance of less than approximately 10% was observed for light having a wavelength of approximately 300 nm to approximately 800 nm.

Thus, it may be seen that the polycrystalline film made of the powder having the average central particle size of approximately 1 μm is more dense than the polycrystalline film made of the powder having the average central particle size of approximately 5 μm, and thus the device characteristics are well implemented.

FIG. 10 is a cross-sectional view illustrating an ultraviolet sensor by the exemplary aerosol deposition according to the present disclosure.

As illustrated in FIG. 10, an ultraviolet sensor 100A by exemplary aerosol deposition according to the present disclosure includes a substrate 110 provided with an electrode 131 having specific resistance less than approximately 100 ohm/cm (e.g., approximately 10 ohm/cm to approximately 100 ohm/cm) on a conductive or insulating substrate, and a polycrystalline film 120 formed by spraying one type of powder or a mixture of several types of powder having an energy band gap of approximately 3 eV to approximately 11 eV onto the substrate 110 and the electrode 131 in a vacuum at a speed of approximately 100 m/s to approximately 500 m/s through a nozzle. Here, the ultraviolet sensor 100A may include a polycrystalline film 120 of which an average central particle size of powder forming the polycrystalline film 120 is 1 nm to 500 nm, and at least one electrode 132 provided on the polycrystalline film 120. In some embodiments, a thickness of the polycrystalline film 120 may be approximately 1 nm to approximately 50 μm. In some embodiments, a lower electrode 131 may be provided on an entire top surface of the substrate 110, and thus, the lower electrode 131 may have a shape that substantially crosses an upper electrode 132.

As a result, in the ultraviolet sensor 100A by the aerosol deposition according to the present disclosure, one electrode 131 may be embedded inside the polycrystalline film 120, and the other electrode 132 may be provided on the surface of the polycrystalline film 120 to minimize a light blocking phenomenon by the electrode, thereby more improving sensor sensitivity.

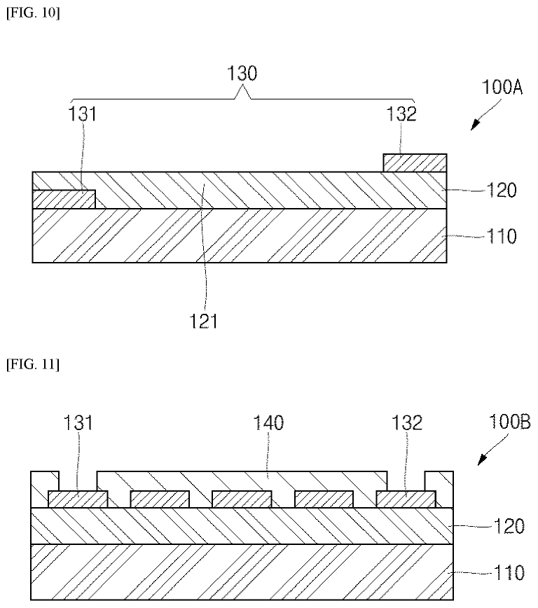

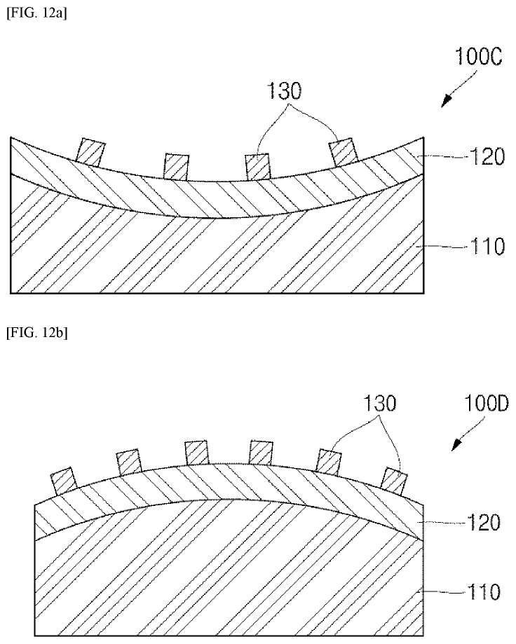

FIG. 11 is a cross-sectional view illustrating an ultraviolet sensor by the exemplary aerosol deposition according to the present disclosure.

As illustrated in FIG. 11, an ultraviolet light sensor 100B by exemplary aerosol deposition according to the present disclosure may further include a protective layer 140 covering a polycrystalline film 120 and an electrode 130. In some embodiments, some areas (e.g., bond pads) of the electrode 130 may be exposed through the protective layer 140 for wire bonding with an external circuit. In some embodiments, the protective layer 140 may include an inorganic layer such as SiO₂, Si₃N₄, or Al₂O₃ or an organic layer such as polyimide. In some embodiments, the inorganic film protective layer 140 may be provided by a CVD or aerosol deposition method, and the organic film protective layer 140 may be provided by a coating or lamination method. In some embodiments, the protective layer 140 may be applied to the present invention if the protective layer 140 is made of a material having light transmittance of approximately 50% to approximately 99.9%.

As a result, in the exemplary ultraviolet sensor 100B according to the present disclosure, the protective layer 140 may protect the electrode 130 from external foreign substances such as moisture or dust to prevent leakage current that may occur between the electrodes facing each other. For example, when a pitch between the electrodes is less than several μm, light sensitivity may decrease due to the leakage current between the electrodes. The protective layer 140 may prevent the leakage current and the decrease in light sensitivity.

FIGS. 12a and 12b are cross-sectional views illustrating an ultraviolet sensor by the exemplary aerosol deposition according to the present disclosure.

As illustrated in FIG. 12a, an ultraviolet sensor 100C may have a structure in which a central region of a substrate 110 and a polycrystalline film 120 is substantially concave. In some embodiments, a thickness of the central region may gradually decreases compared to a thickness of an edge region of the substrate 110 and the polycrystalline film 120 (e.g., similar to a concave lens). The ultraviolet sensor 100C may have improved sensing sensitivity.

As illustrated in FIG. 12b, an ultraviolet sensor 100D may have a structure in which a central region of a substrate 110 and a polycrystalline film 120 is substantially convex. In some embodiments, a thickness of the central region may gradually increase compared to a thickness of an edge region of the substrate 110 and the polycrystalline film 120 (e.g., similar to a convex lens). A sensing area of this ultraviolet sensor 100D may increase.

The above-mentioned embodiment is merely an embodiment of the ultraviolet sensor, and thus, the present disclosure is not limited to the foregoing embodiment, and also it will be understood by those of ordinary skill in the art that various changes in form and details may be made therein without departing from the spirit and scope of the present disclosure as defined by the following claims.

1. An ultraviolet sensor comprising:
a substrate;
a polycrystalline film formed by spraying powder having an energy bandgap of 3 eV to 11 eV and an average central particle size of 0.1 μm to 5 μm onto the substrate in a vacuum at a speed of 100 m/s to 500 m/s through a nozzle, wherein the polycrystalline film has an average central particle size of 1 nm to 500 nm; and
at least two electrodes provided on the polycrystalline film.

2. The ultraviolet sensor as claimed in claim 1, wherein the substrate comprises silicon, quartz, sapphire, a polymer, or a metal.

3. The ultraviolet sensor as claimed in claim 1, wherein the powder comprises at least one of MgF₂, BeO, GaF₂, SiO₂, ZrO₂, MgO, Al₂O₃, AlN, HfO₂, GeO₂, LaAlO₃, diamond, α-Si₃N₄, β-Ga₂O₃, Yb₂O₃, Nd₂O₃, Zn₂GeO₄, Ta₂O₅, MgS, In₂Ge₂O₇, ZnS, NiO, In₂O₃, Zn₂SnO₄, SnO₂, Nb₂O₅, GaN, ZnO, WO₃, CeO₂, 4H-SiC, TiO₂, NgNiO, MgZnO, BeMgZnO, MgZnS, AlGaN, ZrTiO₂, or InGaZnO.

4. The ultraviolet sensor as claimed in claim 1, wherein the polycrystalline film has a thickness of 1 nm to 50 μm.

5. The ultraviolet sensor as claimed in claim 1, wherein the at least two electrodes are provided in an interdigital form on the polycrystalline film.

6. The ultraviolet sensor as claimed in claim 1, wherein the at least two electrodes comprise a first electrode provided on the substrate and a second electrode provided on the polycrystalline film crossing the first electrode.

7. The ultraviolet sensor as claimed in claim 1, wherein each of the electrode has specific resistance less than 100 ohm/cm.

8. The ultraviolet sensor as claimed in claim 1, wherein the polycrystalline film and the electrode are covered by a protective layer, and the protective layer has light transmittance of 50% to 99.9%.

9. The ultraviolet sensor as claimed in claim 1, wherein the ultraviolet sensor is configured to sense light having a wavelength of 10 nm to 400 nm.

10. The ultraviolet sensor as claimed in claim 1, wherein the substrate and the polycrystalline film have a concave structure to improve sensing sensitivity or a convex structure to increase in sealing area.
